(19) United States
(12) Patent Application Publication
(10) Pub. No.: US 2017/0288081 A1
(43) Pub. Date: Oct. 5, 2017

(54) PHOTOVOLTAIC MODULE

(71) Applicant: Merlin Solar Technologies, Inc., San Jose, CA (US)

(72) Inventors: Steve Babayan, Los Altos, CA (US); Robert Brainard, Sunnyvale, CA (US); Arvind Chari, Saratoga, CA (US); Alejandro de la Fuente Vornbrock, San Carlos, CA (US); Venkatesan Murali, San Jose, CA (US); Gopal Prabhu, San Jose, CA (US); Arthur Rudin, Morgan Hill, CA (US); Venkateswaran Subbaraman, San Jose, CA (US); David Tanner, San Jose, CA (US); Dong Xu, Fremont, CA (US); Prashant Ramesh, Mountain View, CA (US); Vishal Chandrashekar, San Jose, CA (US)

(73) Assignee: Merlin Solar Technologies, Inc., San Jose, CA (US)

(21) Appl. No.: 15/630,763

(22) Filed: Jun. 22, 2017

Related U.S. Application Data
(63) Continuation-in-part of application No. 14/775,580, filed on Sep. 11, 2015.
Application No. 14/775,580 is a continuation of application No. 13/798,123, filed on Mar. 13, 2013, now Pat. No. 8,916,038.
Application No. 13/798,123 is a continuation-in-part of application No. 15/601,479, filed on May 22, 2017.
Application No. 15/601,479 is a division of application No. 14/636,864, filed on Mar. 3, 2015, now Pat. No. 9,685,568.
(60) Provisional application No. 61/952,040, filed on Mar. 12, 2014.

(51) Int. Cl. H01L 31/05; H02S 40/34; H01L 31/02

(52) U.S. Cl. CPC H01L 31/0512; H01L 31/0201; H02S 40/34

(57) ABSTRACT

A photovoltaic module has a flexible backing substrate, a plurality of photovoltaic cells, and an electrical conduit. The photovoltaic cells are mounted on the backing substrate. Each photovoltaic cell has a metallic article, the metallic article including a plurality of electroformed elements comprising a cell interconnection element integral with a continuous grid having a plurality of first elements intersecting a plurality of second elements. The electroformed elements are interconnected and integral, with the continuous grid in contact with the light-incident surface of the photovoltaic cell. The cell interconnection element extends beyond the light-incident surface and couples the continuous grid to a neighboring photovoltaic cell. The electrical conduit has a flexible strip of electrically conductive material. The electrical conduit electrically couples the cell interconnection element of a first photovoltaic cell in the plurality of photovoltaic cells to a neighboring second photovoltaic cell in the plurality of photovoltaic cells.

### RELATED APPLICATIONS

This application is a continuation-in-part of U.S. patent application Ser. No. 14/775,580, entitled “Free-Standing Metallic Article for Semiconductors” and filed on Sep. 11, 2015; which claims priority to International Application No. PCT/US2014/022216, entitled “Free-Standing Metallic Article for Semiconductors,” filed on Mar. 10, 2014 and published as WO/2014/159146; which claims priority to U.S. patent application Ser. No. 13/798,123, entitled “Free-Standing Metallic Article for Semiconductors,” filed on Mar. 13, 2013 and issued as U.S. Pat. No. 8,916,038; all of which are hereby incorporated by reference in their entirety.

This application is also a continuation-in-part of U.S. patent application Ser. No. 15/601,479, entitled “Photovoltaic Module with Flexible Circuit” and filed on May 22, 2017; which is a divisional of U.S. patent application Ser. No. 14/636,864, entitled “Photovoltaic Module with Flexible Circuit,” filed on Mar. 3, 2015 and issued as U.S. Pat. No. 9,685,568; which claims priority to U.S. Provisional Patent Application No. 61/952,040, entitled “Photovoltaic Module with Flexible Circuit” and filed on Mar. 12, 2014; all of which are hereby incorporated by reference in their entirety,

### BACKGROUND

A solar cell is a device that converts photons into electrical energy. The electrical energy produced by the cell is collected through electrical contacts coupled to the semiconductor material, and is routed through interconnections with other photovoltaic cells in a module. The “standard cell” model of a solar cell has a semiconductor material, used to absorb the incoming solar energy and convert it to electrical energy, placed below an anti-reflective coating (ARC) layer, and above a metal backsheet. Electrical contact is typically made to the semiconductor surface with fire-through paste, which is metal paste that is heated such that the paste diffuses through the ARC layer and contacts the surface of the cell. The paste is generally patterned into a set of fingers and bus bars which will then be soldered with ribbon to other cells to create a module. Another type of solar cell has a semiconductor material sandwiched between transparent conductive oxide layers (TCO's), which are then coated with a final layer of conductive paste that is also configured in a finger/bus bar pattern.

In both these types of cells, the metal paste, which is typically silver, works to enable current flow in the horizontal direction (parallel to the cell surface), allowing connections between the solar cells to be made towards the creation of a module. Solar cell metallization is most commonly done by screen printing a silver paste onto the cell, curing the paste, and then soldering ribbon across the screen-printed bus bars. However, silver is expensive relative to other components of a solar cell, and can contribute a high percentage of the overall cost.

To reduce silver cost, alternate methods for metallizing solar cells are known in the art. For example, attempts have been made to replace silver with copper, by plating copper directly onto the solar cell. However, a drawback of copper plating is contamination of the cell with copper, which impacts reliability. Plating throughput and yield can also be issues when directly plating onto the cell due to the many steps required for plating, such as depositing seed layers, applying masks, and etching or laser scribing away plated areas to form the desired patterns. Other methods for forming electrical conduits on solar cells include utilizing arrangements of parallel wires or polymeric sheets encasing electrically conductive wires, and laying them onto a cell. However, the use of wire grids presents issues such as undesirable manufacturing costs and high series resistance.

The electrical energy produced by the cell is collected through electrical contacts coupled to the semiconductor material, and is routed through interconnections with other photovoltaic cells to form a photovoltaic module. The interconnections conventionally involve stringing cells together in series or parallel with ribbon bus bars, using two or three ribbons per cell. Conventional interconnections between photovoltaic cells allow only a limited range of motion and spacing for a series of photovoltaic cells. Automated methods for assembling photovoltaic modules have been developed to improve manufacturability and cost, such as using rollable sheets of solar cells, cell stringing machines and automated lamination. The cell strings are then connected to one or more junction boxes for the entire module using final ribbon runs. The final ribbon connections from the cells to the junction box are typically cut and soldered by hand.

A photovoltaic module also includes one or more bypass diodes to protect the module when cells within the module are not operating properly, such as due to damage or shading. A shaded cell reverse biases and consequently draws current from the module instead of producing current, which can result in electrical arcing and even fire, or hot spotting as referred to in the industry. In typical modules, one diode is required for a certain number of cells, such as approximately for every 18-24 solar cells. These diode connections add to the manufacturing steps that are required for assembling a photovoltaic module. Thus, numerous ribbon soldering steps and bypass diode connections are involved in fabricating a photovoltaic module, especially for large modules such as with sixty or more solar cells.

### SUMMARY

In some embodiments, a photovoltaic module includes a flexible backing substrate, a plurality of photovoltaic cells mounted on the flexible backing substrate, and an electrical conduit. Each photovoltaic cell includes a metallic article. The metallic article has a plurality of electroformed elements configured as an electrical component for a light-incident surface of the photovoltaic cell. The plurality of electroformed elements has a cell interconnection element integral with a continuous grid having a plurality of first elements intersecting a plurality of second elements. The plurality of electroformed elements is interconnected and integral, with the continuous grid in contact with the light-incident surface. The cell interconnection element is configured to extend beyond the light-incident surface and couples the continuous grid to a neighboring photovoltaic cell. The electrical conduit includes a flexible strip of electrically conductive material. The electrical conduit electrically couples the cell interconnection element of a first photovoltaic cell in the plurality of photovoltaic cells to a neighboring second photovoltaic cell in the plurality of photovoltaic cells.

In some embodiments, a method of forming a photovoltaic module includes providing a flexible backing substrate and mounting a plurality of photovoltaic cells on the flexible backing substrate. Each photovoltaic cell includes a metallic article. The metallic article has a plurality of electroformed elements configured as an electrical component for a light-incident surface of the photovoltaic cell. The plurality of electroformed elements has a cell interconnection element integral with a continuous grid having a plurality of first elements intersecting a plurality of second elements. The plurality of electroformed elements is interconnected and integral, with the continuous grid in contact with the light-incident surface. The cell interconnection element is configured to extend beyond the light-incident surface and couples the continuous grid to a neighboring photovoltaic cell. The method also includes electrically coupling the cell interconnection element of a first photovoltaic cell in the plurality of photovoltaic cells to a neighboring second photovoltaic cell in the plurality of photovoltaic cells using an electrical conduit. The electrical conduit comprises a flexible strip of electrically conductive material.

### BRIEF DESCRIPTION OF THE DRAWINGS

Each of the aspects and embodiments of the invention described herein can be used alone or in combination with one another. The aspects and embodiments will now be described with reference to the attached drawings.

FIG. 1A is a perspective view of a conventional solar cell.

FIG. 1B is a cross-sectional view of a conventional back-contact solar cell.

FIG. 2 shows a perspective view of an electroforming mandrel in accordance with some embodiments.

FIGS. 3A-3C depict cross-sectional views of stages in producing a free-standing electroformed metallic article, in accordance with some embodiments.

FIG. 4 provides a cross-sectional view of an electrically conductive mandrel, in accordance with some embodiments.

FIG. 5 provides a cross-sectional view of another embodiment of an electrically conductive mandrel.

FIG. 6 illustrates a cell-to-cell interconnection between an embodiment of a front mesh and back mesh as disclosed in U.S. patent application Ser. No. 14/079,540.

FIG. 7 is a flow chart of a method for manufacturing an electroformed article and forming a semiconductor device such as a solar cell, in accordance with some embodiments.

FIG. 8 is an exploded assembly view of a photovoltaic module with metallic articles and a flexible module circuit, in accordance with some embodiments.

FIG. 9 shows a top view of a flexible module with fold lines, in accordance with some embodiments.

FIG. 10 shows a top view of another embodiment of a flexible module.

FIG. 11 provides a top view of further embodiment of a flexible module, with bi-directional folding capability.

FIG. 12 is a top view of a flexible solar cell using a metallic article as described herein.

FIGS. 13A-13B are plan views of flexible electrical conduits for interconnecting solar cells, in accordance with some embodiments.

FIG. 14 is a plan view of photovoltaic cells coupled by flexible electrical conduits, in accordance with some embodiments.

FIG. 15 is a top view of a flexible circuit for a photovoltaic module, in accordance with some embodiments.

### DETAILED DESCRIPTION OF THE EMBODIMENTS

Flexible photovoltaic modules are described herein, which use mechanically flexible components such as electrical conduits for interconnecting photovoltaic cells, flexible module circuits for module-level electrical connections, and cell-to-cell interconnection elements that are integral to the metallization of a photovoltaic cell. The metallization components for a cell are electroformed, free-standing metallic articles that serve as the electrical component for the front or back surface of a photovoltaic cell. The photovoltaic modules can be made using a flexible backing substrate or a rigid substrate, where fold lines can be incorporated into either type of substrate. The components disclosed herein for coupling photovoltaic cells together in a flexible photovoltaic module enable electrically efficient, flexurally durable, and automatable connections for ease of manufacturing.

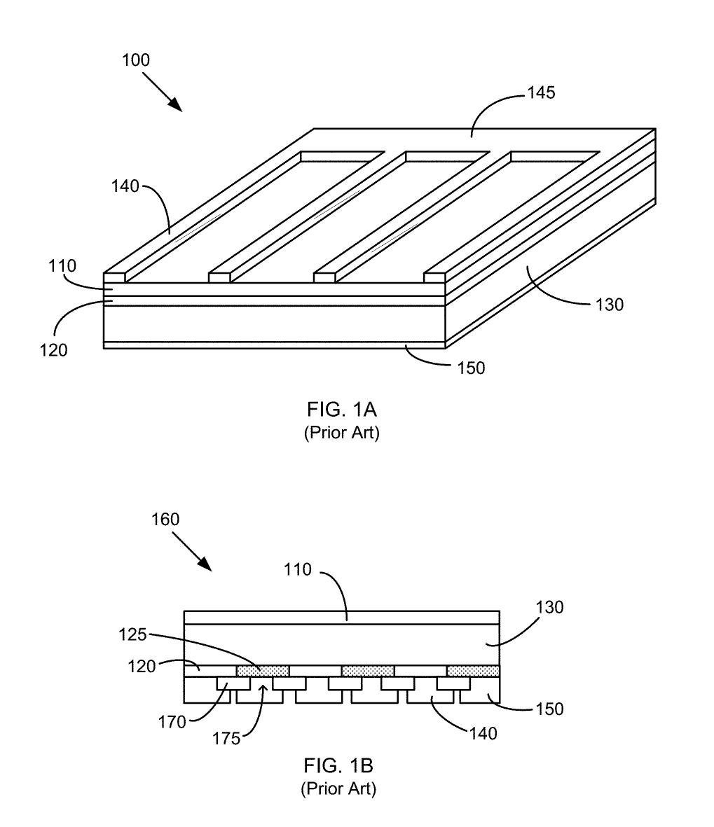

FIG. 1A is a simplified schematic of a conventional solar cell 100 which includes an anti-reflective coating (ARC) layer 110, an emitter 120, a base 130, front contacts 140, and a rear contact layer 150. Emitter 120 and base 130 are semiconductor materials that are doped as p+ or n− regions, and may be referred to together as an active region of a solar cell. Front contacts 140 are typically fired through anti-reflective coating layer 110 in order to make electrical contact with the active region. Incident light enters the solar cell 100 through ARC layer 110, which causes a photocurrent to be created at the junction of the emitter 120 and base 130. It can be seen that shading caused by front contacts 140 will affect the efficiency of the cell 100. The produced electrical current is collected through an electrical circuit connected to front contacts 140 and rear contact 150. A bus bar 145 may connect the front contacts 140, which are shown here as finger elements. Bus bar 145 collects the current from front contacts 140, and also may be used to provide interconnection between other solar cells. The assembly of front contacts 140 and bus bar 145 may also be referred to as a metallization layer. In other types of solar cells, a transparent conductive oxide (TCO) layer may be used instead of a dielectric-type ARC layer, to collect electrical current. In a TCO type of cell, metallization in the form of, for example, front contacts 140 and bus bar 145 would be fabricated onto the TCO layer, without the need for firing through, to collect current from the TCO solar cell.

FIG. 1B illustrates a simplified schematic of another type of solar cell 160, in which the electrical contacts are made on the back side, opposite of where light enters. Solar cell 160, also known as an interdigitated back contact cell, includes an ARC layer 110, a base region 130 made of a semiconductor substrate, and doped regions 120 and 125 having opposite polarities from each other (e.g., p-type and n-type). Doped regions 120 and 125 are on the back side of cell 160, opposite of ARC layer 110. A non-conducting layer 170 provides separation between the doped regions 120 and 125, and also completes the role of passivation of the back surface of cell 160. Electrical contacts 140 and 150 are interdigitated with each other and make electrical connections to doped regions 120 and 125, respectively, through holes 175 in the passivating layer 170. Although the electrical contacts 140 and 150 do not present a shading issue in this back-contact type of solar cell, they may still present other issues such as manufacturing yield losses when forming the contacts onto the cell, high material costs if using silver for the contacts, or degradation of the cell if using copper for the contacts.

Metallization of solar cells typically involves screen printing a silver paste in the desired pattern of the electrical contacts to be connected to the cell. In FIG. 1A, the front contacts 140 are configured in a linear pattern of parallel segments. Because the cost of silver can add greatly to the expense of the solar cell, it is highly desirable to reduce or even eliminate the use of silver. Copper is an attractive alternative to silver because of its high electrical conductivity, but can lead to contamination of the semiconductor materials and consequently reduced performance of the solar cell. Known methods of utilizing copper in solar cells involve depositing copper directly onto the cell. However, these methods require subjecting the solar cells to the temperatures and chemicals involved with the many steps during these plating processes, which can cause damage to the cell. In other known methods, arrangements of parallel copper wires or woven grids of wires are produced separately from the cell, and then joined to the cell. However, with these methods it can be difficult to align the wires to the cell, or to produce wires small enough to be functional but yet minimize shading on a solar cell. Wire grids encapsulated within polymeric films have also been produced, but these methods can be complex and still present shading and alignment problems, particularly due to the presence of the polymeric sheet. Copper paste is another alternative, but these pastes can be difficult to apply and still present the problem of diffusion into the solar cell.

In the present disclosure, electrical components for semiconductors, such as photovoltaic cells, are fabricated as an electroformed free-standing metallic article. The metallic articles are produced separately from a solar cell and can include multiple elements such as fingers and bus bars that can be transferred stably as a unitary piece and easily aligned to a semiconductor device. The elements of the metallic article are formed integrally with each other in the electroforming process. The metallic article is manufactured in an electroforming mandrel, which generates a patterned metal layer that is tailored for a solar cell or other semiconductor device. For example, the metallic article may have grid lines with height-to-width aspect ratios that minimize shading for a solar cell. The metallic article can replace conventional bus bar metallization and ribbon stringing for cell metallization, cell-to-cell interconnection and module making. The ability to produce the metallization layer for a photovoltaic cell as an independent component that can be stably transferred between processing steps provides various advantages in material costs and manufacturing.

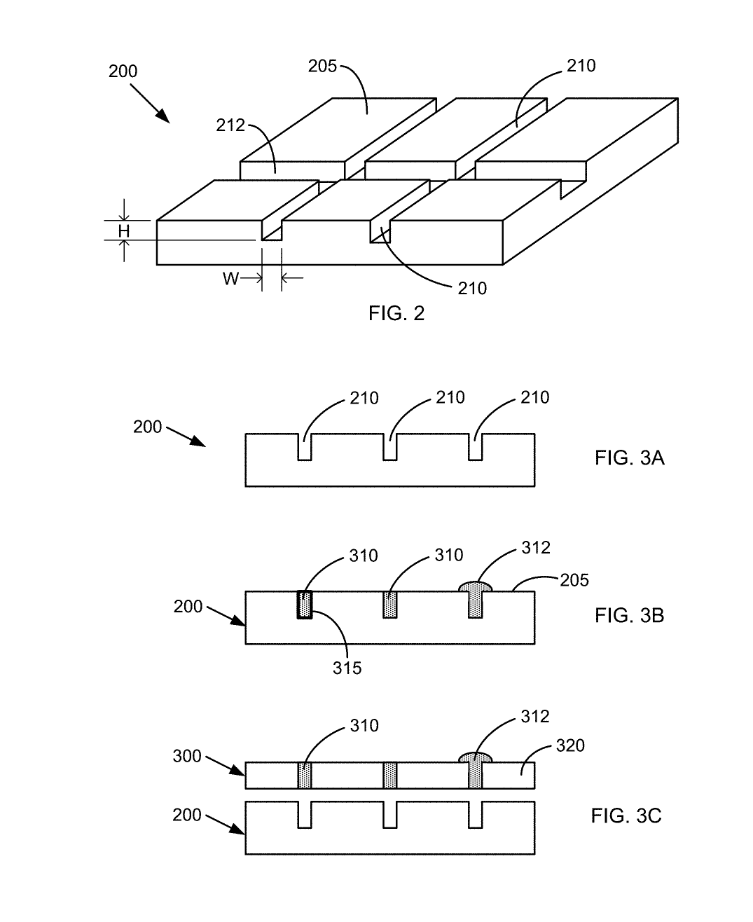

FIG. 2 depicts a perspective view of a portion of an example electroforming mandrel 200 in one embodiment. The mandrel 200 may be made of electrically conductive material such stainless steel, copper, anodized aluminum, titanium, or molybdenum, nickel, nickel-iron alloy (e.g., Invar), copper, or any combinations of these metals, and may be designed with sufficient area to allow for high plating currents and enable high throughput. The mandrel 200 has an outer surface 205 with a preformed pattern that comprises pattern elements 210 and 212 and can be customized for a desired shape of the electrical conduit element to be produced. In this embodiment, the pattern elements 210 and 212 are grooves or trenches with a rectangular cross-section, although in other embodiments, the pattern elements 210 and 212 may have other cross-sectional shapes. The pattern elements 210 and 212 are depicted as intersecting segments to form a grid-type pattern, in which sets of parallel lines intersect perpendicularly to each other in this embodiment.

The pattern elements 210 have a height ‘H’ and width ‘W’, where the height-to-width ratio defines an aspect ratio. By using the pattern elements 210 and 212 in the mandrel 200 to form a metallic article, the electroformed metallic parts can be tailored for photovoltaic applications. For example, the aspect ratio may be between about 0.01 and about 10. In some embodiments, the aspect ratio can be designed to be greater than 1, such as between about 1 and about 10, or between about 1 and about 5. Having a height greater than the width allows the metal layer to carry enough current but reduce the shading on the cell compared to, for example, standard circular wires which have an aspect ratio of 1, or compared to conventional screen-printed patterns which are horizontally flat and have aspect ratios less than 1. Shading values for screen-printed metal fingers may be, for example, over 6%. With metallic articles having tailored aspect ratios as described herein, shading values of less than 6% may be achieved, such as between 4-6%. Thus, the ability to produce electrical conduits with aspect ratios greater than 1 enable minimal aperture loss to a photovoltaic cell, which is important to maximizing efficiency. In embodiments where the electroformed electrical conduit is used on a back surface of a solar cell, aspect ratios of other values, such as less than 1, may be used.

The aspect ratio, as well as the cross-sectional shape and longitudinal layout of the pattern elements, may be electroformed to meet desired specifications such as electrical current capacity, series resistance, shading losses, and cell layout. Any electroforming process can be used. For example, the metallic article may be formed by an electroplating process. In particular, because electroplating is generally an isotropic process, confining the electroplating with a pattern mandrel to customize the shape of the parts is a significant improvement for maximizing efficiency. Furthermore, although tall yet narrow conduit lines typically would tend to be unstable when placing them on a semiconductor surface, the customized patterns that may be produced through the use of a mandrel allows for features such as interconnecting lines to provide stability for these tall but narrow conduits. In some embodiments, for example, the preformed patterns may be configured as a continuous grid with intersecting lines. This configuration not only provides mechanical stability to the plurality of electroformed elements that form the grid, but also enables a low series resistance since the current is spread over more conduits. A grid-type structure can also increase the robustness of a cell. For example, if some portion of the grid becomes broken or non-functional, the electrical current can flow around the broken area due to the presence of the grid pattern.

FIGS. 3A-3C are simplified cross-sectional views of stages in producing a metal layer piece using a mandrel, in accordance with some embodiments. In FIG. 3A, a mandrel 200 with pattern elements 210 is provided. The mandrel 200 is subjected to an electroforming process, in which electroformed elements 310 are formed within the pattern elements 210 as shown in FIG. 3B. In the embodiment of FIGS. 3A-3C, the pattern elements 210 have been designed with a higher aspect ratio than those in FIG. 2. The electroformed elements 310 may be, for example, copper only, or in other embodiments, alloys of copper. In other embodiments, a layer of nickel may be plated onto the mandrel 200 first, followed by copper so that the nickel provides a barrier against copper contamination of a finished semiconductor device. An additional nickel layer may optionally be plated over the top of the electroformed elements 310 to encapsulate the copper, as depicted by nickel layer 315 in FIG. 3B. In other embodiments, multiple layers may be plated within the pattern elements 210, using various metals as desired to achieve the necessary properties of the metallic article to be produced.

In FIG. 3B the electroformed elements 310 are shown as being formed flush with the outer surface 205 of mandrel 200. Electroformed element 312 illustrates another embodiment in which the elements may be overplated. For electroformed element 312, electroplating continues until the metal extends above the surface 205 of mandrel 200. The overplated portion, which typically will form as a rounded top due to the isotropic nature of electroforming, may serve as a handle to facilitate the extraction of the electroformed element 312 from mandrel 200. The rounded top of electroformed element 312 may also provide optical advantages in a photovoltaic cell by, for example, being a refractive surface to aid in light collection. In yet other embodiments not shown, a metallic article may have portions that are formed on top of the surface 205, such as a bus bar, in addition to those that are formed within the preformed patterns 210.

In FIG. 3C the electroformed elements 310 are removed from the mandrel 200 as a free-standing metallic article 300. The electroformed elements 310 may include intersecting elements 320, such as would be formed by patterns 212 of FIG. 2. The intersecting elements 320 may assist in making the metallic article 300 a unitary, free-standing piece such that it may be easily transferred to other processing steps while keeping the individual elements 310 and 320 aligned with each other. The additional processing steps may include coating steps for the free-standing metallic article 300 and assembly steps to incorporate it into a semiconductor device. By producing the metal layer of a semiconductor as a free-standing piece, the manufacturing yields of the overall semiconductor assembly will not be affected by the yields of the metal layer. In addition, the metal layer can be subjected to temperatures and processes separate from the other semiconductor layers. For example, the metal layer may undergo high temperature processes or chemical baths that will not affect the rest of the semiconductor assembly.

After the metallic article 300 is removed from mandrel 200 in FIG. 3C, the mandrel 200 may be reused to produce additional parts. Being able to reuse the mandrel 200 provides a significant cost reduction compared to current techniques where electroplating is performed directly on a solar cell. In direct electroplating methods, masks or mandrels are formed on the cell itself, and thus must be built and often destroyed on every cell. Having a reusable mandrel reduces processing steps and saves cost compared to techniques that require patterning and then plating a semiconductor device. In other conventional methods, a thin printed seed layer is applied to a semiconductor surface to begin the plating process. However, seed layer methods result in low throughputs. In contrast, reusable mandrel methods as described herein can utilize mandrels of thick metal which allow for high current capability, resulting in high plating currents and thus high throughputs. Metal mandrel thicknesses may be, for example, between 0.2 to 5 mm.

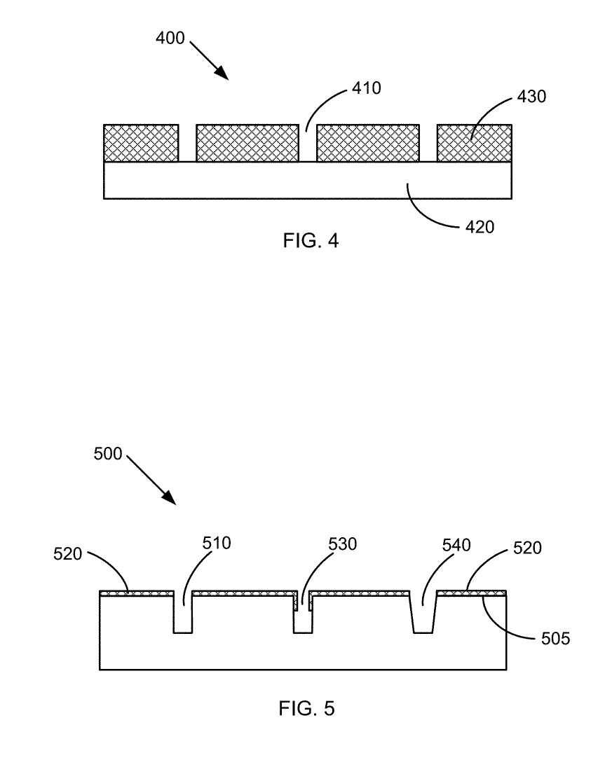

FIGS. 4-5 are cross-sectional views of electroforming mandrels, demonstrating embodiments of various mandrel and pattern designs. In FIG. 4, a planar metal mandrel base 420 has a dielectric layer 430 laid over it. The pattern including pattern elements 410 for forming a metallic article are created in dielectric layer 430. The dielectric layer 430 may be, for example, a fluoropolymer (e.g., Teflon®), a patterned photoresist (e.g., Dupont Riston® thick film resist), or a thick layer of epoxy-based photoresist (e.g., SU-8). The photoresist is selectively exposed and removed to reveal the desired pattern. In other embodiments, the dielectric layer 430 may be patterned by, for example, machining or precision laser cutting. In this type of mandrel 400 with dielectric-surrounded pattern elements, electroplating will fill the trenches of pattern elements 410 from the bottom up, starting at the metal mandrel base 420. The use of dielectrics or permanent resists allows for reuse of the mandrel 400, which reduces the number of process steps, consumable costs, and increases throughput of the overall manufacturing process compared to consumable mandrels.

FIG. 5 shows another mandrel 500 made primarily of metal, including the cavities for forming a metallic article. When electroforming with metal mandrel 500, the metal surfaces of a pattern element 510 allow for rapid plating from all three sides of the trench pattern. In some embodiments of mandrel 500, a release layer 520 such as a dielectric or low-adhesion material (e.g., a fluoropolymer) may optionally be coated onto the mandrel 500, in various areas as desired. The release layer 520 may reduce adhesion of the electroformed part to the mandrel 500, or may minimize adhesion of a substrate, such as an adhesive film, that may be used to peel the electroformed article from the mandrel. The release layer 520 may be patterned simultaneously with the metal mandrel, or may be patterned in a separate step, such as through photoresist with wet or dry etching. The pattern elements 510, 530 and 540 in the metal mandrel, may be, for example, grooves and intersecting trenches, and may be formed by, for instance, machining, laser cutting, lithography, or electroforming. In other embodiments, the mandrel 500 may not require a release layer 520 if the surface of the mandrel that is exposed to the plating solution is selected to have poor adhesion to the metallic article. For instance, for electroformed parts that will have a first layer (that is, an outer layer) of nickel plating, the mandrel 400 may be made of copper. Copper has low adhesion to nickel and thereby allows the formed, nickel-coated piece to be easily removed from the copper mandrel. When applying a release layer 520 to mandrel 500, the relative depth of the trench pattern element 510 in the metal and the thickness of the dielectric coating can be selected to minimize void formation of the metal piece formed within pattern element 510, while still enabling a high plating rate.

FIG. 5 shows a further embodiment in which the release layer 520 has been extended partially into the depth of pattern element 530. This extension of the coating into pattern element 530 may enable electroforming rates between that of dielectrically-surrounded pattern element 410 of FIG. 4 and metal-surrounded pattern element 510 of FIG. 5. The amount that release layer 520 extends into the pattern element 530 may be chosen to achieve a desired electroforming rate. In some embodiments, release layer 520 may extend into pattern element 530 by, for example, approximately half the amount of the pattern width. A pattern element 530 with release layer 520 extending into the trench can allow a more uniform electroplating rate within the trench, and hence, a more uniform grid can be produced. The amount that the dielectric or release layer 520 extends into the trench can be modified to optimize overall plating rate and plating uniformity.

FIG. 5 shows yet another embodiment of mandrel 500 in which the pattern element 540 has tapered walls. The tapered walls are wider at the outer surface 505 of mandrel 500, to facilitate removal of a formed metallic element from the patterned mandrel. In other embodiments not shown, the cross-sectional shape of the preformed patterns for any of the mandrels described herein may include shapes such as, but not limited to, curved cross-sections, beveled edges at the corners of a pattern's cross-section, curved paths along the length of a pattern, and segments intersecting each other at various angles to each other.

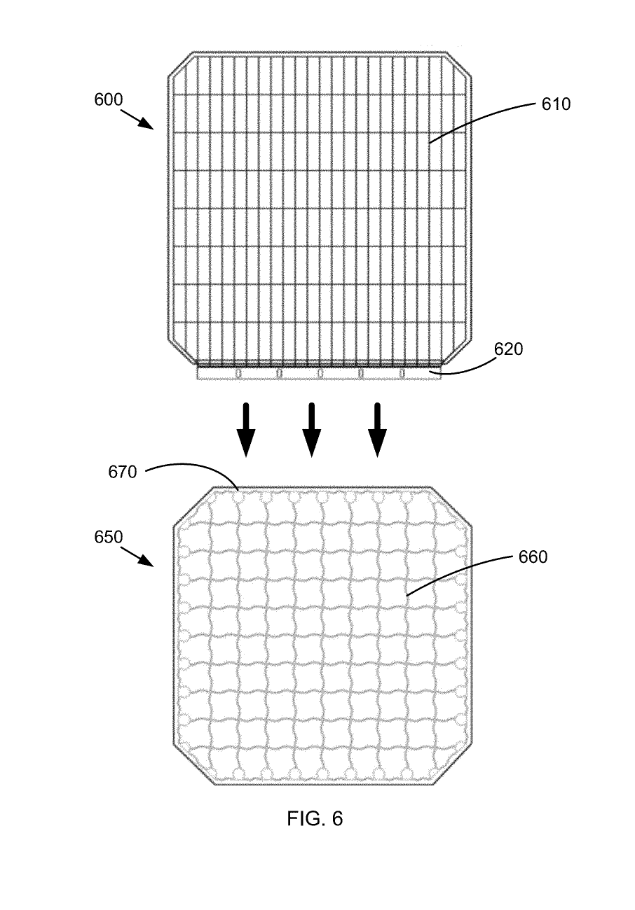

FIG. 6 shows a top view of an embodiment of a metallic article 610 produced by the electroforming mandrels of the present disclosure, where the metallic article has a front-to-back cell-to-cell interconnection between two photovoltaic cells as disclosed in Babayan et al., U.S. Pat. No. 8,936,709, entitled “Adaptable Free-Standing Metallic Article for Semiconductors,” which is owned by the assignee of the present disclosure and is hereby incorporated by reference. Solar cell 600 has the metallic article 610 mounted on the front side of the cell, where the metallic article 610 includes an interconnect element 620 at one edge. Interconnect 620 is joined to the back side of cell 650, which has a metallic article 660 configured as a back side mesh. The joining may be achieved by, for example, soldering, welding, ultrasonic, conductive adhesive, or other electrical bonding methods.

The interconnect 620 is bonded to the bus bar 670 of metallic article 660 for a series connection between cells 600 and 650. The interconnect 620 may be integrally formed with the gridlines of the metallic article 610, or may be a separate piece that is joined to the grid. In certain embodiments, the interconnection elements may extend beyond the edge of the photovoltaic cell such that there is spacing and consequently flexure that is enabled between cells. This enables the overall module to withstand deflection, such as during transport or due to environmental stresses in the installed location. In some embodiments, both the front metallic article 610 and the back metallic article 660 may have cell-to-cell interconnection elements, such as interconnect 620. In further embodiments, the back metallic article 660 may have an interconnection element while the front metallic article 610 does not. Interconnection element 620 in this embodiment spans substantially an entire edge of metallic article 610, such that it is coupled to the plurality of gridlines of the metallic article 610. Thus, one solder joint with the cell interconnection element 620 enables electrical connection to the entire cell in which the metallic article is used, which is simplified from, for example, three solder ribbons as in conventional cells. The interconnection element 620 may or may not extend beyond the top or bottom surface of the semiconductor substrate of a photovoltaic cell, such as to allow for overlap with an adjacent cell, as well as to allow for easy connection to a flexible circuit or electrical conduit interconnection as shall be described subsequently.

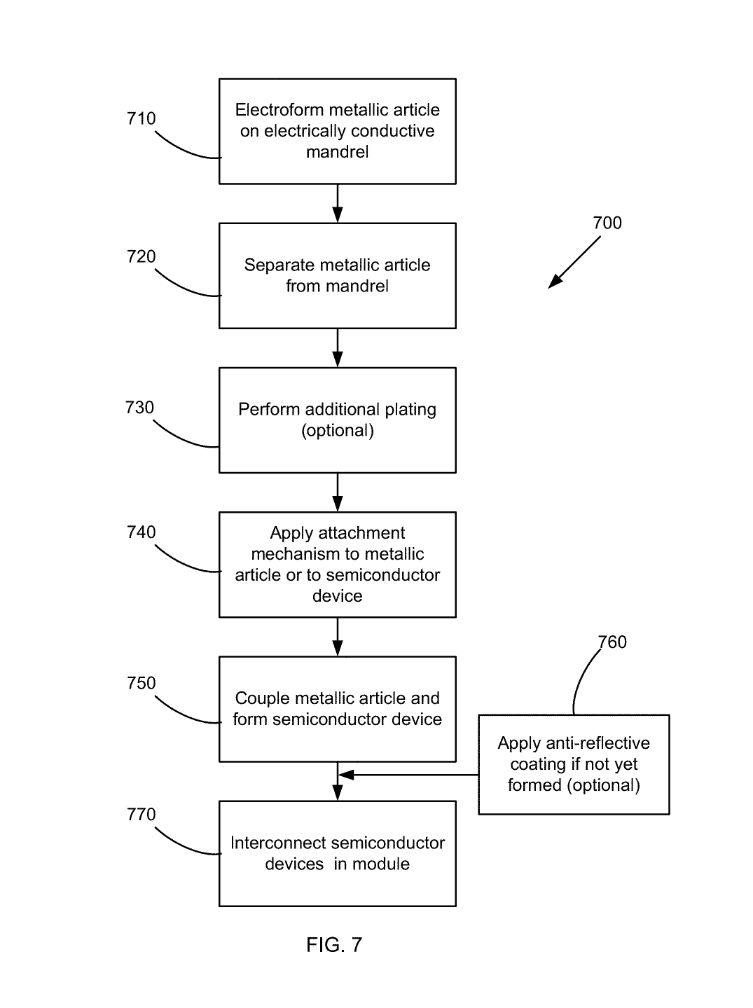

FIG. 7 depicts a flow chart 700 for fabricating a free-standing electroformed metallic article for use with a semiconductor assembly such as a photovoltaic cell. In this disclosure, reference to semiconductor materials in formation of a semiconductor device or photovoltaic cell may include amorphous silicon, crystalline silicon or any other semiconductor material suitable for use in a photovoltaic cell. In a step 710, an electroforming process is performed using an electrically conductive mandrel. The mandrel has one or more preformed patterns in which to form a metallic article. In some embodiments, the metallic article is configured to serve as an electrical component within a photovoltaic cell. In certain embodiments, the metallic article may include features to enable connections between photovoltaic cells of a solar module. The preformed pattern may have an aspect ratio of greater than 1, and may include multiple parallel patterns intersecting each other. At least a portion of the finished electroformed metallic article is created within the preformed patterns. Other portions of the metallic article, such as a bus bar, may be formed within preformed patterns or on a top surface of the mandrel.

The electroforming step 710 may include contacting the outer surface of the mandrel with a solution comprising a salt of a first metal, where the first metal may be, for example copper or nickel. The first metal may form the entire metallic article, or may form a metallic precursor for layers of other metals. For example, a solution of a salt comprising a second metal may be plated over the first metal. In some embodiments, the first metal may be nickel and the second metal may be copper, where the nickel provides a barrier for copper diffusion. A third metal may optionally be plated over the second metal, such as the third metal being nickel over a second metal of copper, which has been plated over a first metal of nickel. In this three-layer structure, the copper conduit is encapsulated by nickel to provide a barrier against copper contamination into a semiconductor device. Electroforming process parameters in step 710 may be, for example, currents ranging from 1 to 3000 amps per square foot (ASF) and plating times ranging from, for example, 1 minute to 200 minutes. Other electrically conductive metals may be applied to promote adhesion, promote wettability, serve as a diffusion barrier, or to improve electrical contact, such as tin, tin alloys, indium, indium alloys, bismuth alloys, nickel tungstate, or cobalt nickel tungstate.

After the metallic article is formed, the metallic article is separated in step 720 from the electrically conductive mandrel to become a free-standing, unitary piece. The separation may involve lifting or peeling the article from the mandrel, with or without the use of a temporary polymeric sheet, or with or without the use of vacuum handling. In other embodiments, removal may include thermal or mechanical shock or ultrasonic energy to assist in releasing the fabricated part from the mandrel. The free-standing metallic article is then ready to be formed into a photovoltaic cell or other semiconductor device, by attaching and electrically coupling the article as shall be described below. Transferring of the metallic article to the various manufacturing steps may be done without need for a supporting element, such as a plastic or polymeric substrate, which can reduce cost.

The free-standing metallic article may be mounted directly to a solar cell or may undergo additional processing steps prior to being attached. Note that for the purposes of this disclosure, the term “metallic article” may also be interchangeably referred to as a grid or mesh, even though some embodiments may not include intersecting cross-members. If the metallic article has been formed without a barrier layer, the separated, free-standing metallic article may optionally undergo additional plating operations in step 730. For example, nickel plating may be performed by, for example, electroless or electroplating. In some embodiments, the metallic article may also be plated with nickel-cobalt-tungsten or cobalt-tungsten-phosphorous to create a diffusion barrier for copper material at high temperatures, while the standard nickel plating prevents copper migration in the cell below 300° C.

After any additional plating has been completed, in step 740 an attachment mechanism may be applied to the free-standing metallic article to prepare it for being mounted to a cell surface. For a standard solar cell model, a reactive metal layer such as a fire-through silver paste may be applied to the surface of the metallic article that is to be coupled to the solar cell. The reactive paste provides the electrical connection between the metallic article and the semiconductor layer, and may be thinly applied. The paste may be applied to the electroformed metallic article by, for example, screen printing. The amount of silver that is applied to the grid is much less than that which is required when forming the metallization layer solely from fire-through paste. Because the fire-through paste is applied onto the grid rather than the solar cell, the electrical coupling between the grid and solar cell is self-aligned. That is, there is no need to align the fingers of the metallic article to conductive lines of paste that have been applied onto the solar cell, thus simplifying the manufacturing process. Furthermore, in conventional methods, extra paste is often applied to ensure alignment with electrical contacts. In contrast, the present methods enable the application of silver paste only where necessary. Additional methods of applying the attachment mechanism include electroplating; electroless plating; wave soldering; physical vapor deposition techniques such as evaporation or sputtering; dispensing via ink-jet or pneumatic dispensing techniques; or thin film transfer techniques such as stamping the grid onto a thin film of molten solder or metal.

While some types of solar cells use dielectric ARC's, other types use conductive ARC's, such as TCO's. For TCO types of solar cells, such as those coated with indium-tin-oxide (ITO), the attachment mechanism in step 740 may be solder, such as a low temperature solder. The solder is applied to the surface of the grid that will be in contact with the cell. By applying solder to the grid, a minimal amount of solder is used, thus reducing material cost. In addition, the solder is self-aligned with the grid pattern. The type of solder on the metallic article may be chosen for characteristics such as good ohmic contact and electrical conductivity, strong adhesion, rapid thermal dissipation, low coefficient of thermal expansion (CTE) mismatch with the targeted surface, robust mechanical stress relief, high mechanical strength, solid electrical migration barrier, adequate wettability, and chemically sound material inter-diffusion barriers between the metallic electroformed grid and the surface of the solar cell. In one embodiment, a no-clean solder may be applied. In another embodiment, an electroless or electroplated low melting point metal or alloy—such as, but not limited to, indium, indium-tin, indium-bismuth, lead-tin-silver-copper, lead-tin-silver, and lead-indium—may be applied to the grid. In a further embodiment, a solder paste may be printed onto the grid. The solder paste may require a drying process before the grid and the solar cell can be coupled together. In yet another embodiment, the tips—that is, the bottom surface—of the grid may be dipped or immersed into a liquid solder, which will selectively attach to the mesh surface.

Although the attachment mechanisms above have been described as being applied to the electroformed article, in other embodiments, step 740 may include applying the fire-through paste or solder material to the solar cell. The electroformed article would then be brought into contact with the conductive patterns made by the paste or solder. The metallic article may be prepared for contacting with the cell by optionally applying an indium metal or indium alloy to the article. The indium can be electroplated onto the surface of the grid by dipping the grid into the electrolyte while providing current. In another embodiment, the grid may be coated by an electroless plating method by dipping it into a solution of indium. The grid can be dipped first into a molten flux, which removes oxide on the tips of the grid, and then into an indium tin solder such that only the tips of the grid are wetted with the indium tin solder. In another embodiment, the grid can be dipped into indium tin paste followed by an anneal step, again with only the tips of the grid being coated. Coating of only the tip, and not the entire grid, with indium preserves precious indium while still achieving a contactable surface. Once indium-tipped, the fingers or elements of the electroformed article may then be aligned with the fire-through paste or solder on the cell by, for example, optical alignment marks on edges of the solar cell.

In further embodiments, the metallic articles may be utilized in back-contact types of solar cells, such as those illustrated in FIG. 1B, using similar methods. An attachment mechanism, which would typically be solder, is applied to either the metallic article or the solar cell in step 740, and the metallic article is then contacted with the cell. The attachment mechanism is heated to electrically couple the metallic article with the cell. In one embodiment of back-contact solar cells, the electroformed elements of a first metallic article would be coupled to the p-type regions on the rear surface of the cell, while the electroformed elements of a second metallic article would be coupled to the n-type regions. For example, the metallic articles could be configured with linear fingers, and the fingers of the first metallic article would be interdigitated with the fingers of the second metallic article.

After an attachment mechanism has been applied to the metallic article, the metallic article is coupled to the cell or semiconductor device surface in step 750. The metallic article is brought into contact with the surface of the solar cell. If the grid article has been tipped with fire-through silver paste, the assembly is heated to the fire-through temperature of the paste, such as to temperatures of at least 400° C., or at least 800° C. The grid may be held mechanically stable during firing by the use of rollers or clamps. Once the fire-through paste is set, neighboring solar cells in a module may be interconnected. For solder-tipped grids, the grid is similarly coupled to the solar cell and heated to temperatures required for the particular solder typically ranging between 100° C. and 300° C. A thermal and/or pressure process in atmosphere or vacuum may be used to reflow the solder and form the contacts between the metallic article and the solar cell.

In some embodiments, the independent grid or metallic article, after being plated with the desired barrier layers, can be attached to a solar cell prior to anti-reflective coating layer deposition. In a standard cell, the grid can be contacted to the emitter surface (e.g., doped silicon) and heated to create a nickel silicide chemical bond. The ARC, such as a nitride, can then be deposited after grid attachment, in optional step 760. A bus bar of the grid can then be connected to another cell in the module. This embodiment of attaching the grid before the ARC layer eliminates the need for any silver fire-through usage. In addition, this embodiment may be applied to silicon heterojunction solar cells. For instance, the free-standing metallic article, such as a grid, can be coupled to the surface of the heterojunction cell amorphous silicon layer. It can then be heated to create a nickel silicide bond, and the ITO layer can be deposited on the grid afterwards.

After the completed photovoltaic cell has been formed in step 750, the multiple cells that form a solar module may be interconnected in step 770. In some embodiments, the bus bars or tabs that have been electroformed as part of the metallic article may be utilized for these interconnections. In some embodiments, cell interconnection elements that are integral to the metallic articles can be used to interconnect the solar cells of a module together, such as electrically coupling them in series. In some embodiments, separate electrical conduit pieces can be used to electrically couple the solar cells of a module together. In some embodiments, the electrical conduit pieces can be used instead of or in addition to the cell interconnection elements. For example, integral cell interconnection elements may be used to interconnect some solar cells of a solar module, while separate electrical conduits can be used to interconnect other solar cells of the module.

It can be seen that the free-standing electroformed metallic article described herein is applicable to various cell types and may be inserted at different points within the manufacturing sequence of a solar cell. Furthermore, the electroformed metallic articles may be utilized on either the front surface or rear surface of a solar cell, or both. When electroformed articles are used on both front and back surfaces, they may be applied simultaneously to avoid any thermal expansion mismatch which may cause mechanical bending of the cells.

The use of an electroformed metallic article as described herein enables the preparation of a wide variety of different photovoltaic cells and solar cell modules. The electroformed metallic article may be inserted at different points within the manufacturing sequence. In addition, the metallic articles can be specifically designed in order to efficiently produce cells and modules with additional combinations of benefits and properties that are not readily possible currently. For example, since the metallic article can be a unitary piece spanning and crossing essentially the entire surface of the cell, improved durability results. In particular, should the solar cell develop a crack, such as during handling or module production, the metallic article enables the fractured cell to be held intact due to the grid-like nature of the metallic article, with minimal functional loss to the cell. In addition, the spanning of the metallic article across the cell surface reduces the impact of solder joint failures. Furthermore, since an electroformed metallic article can be produced with consistent and predictable thicknesses throughout, current is carried evenly across a cell. This even distribution of current dramatically reduces the development of hot spots on the cell surface, which is presently a primary cause of degradation and damage of solar cells.

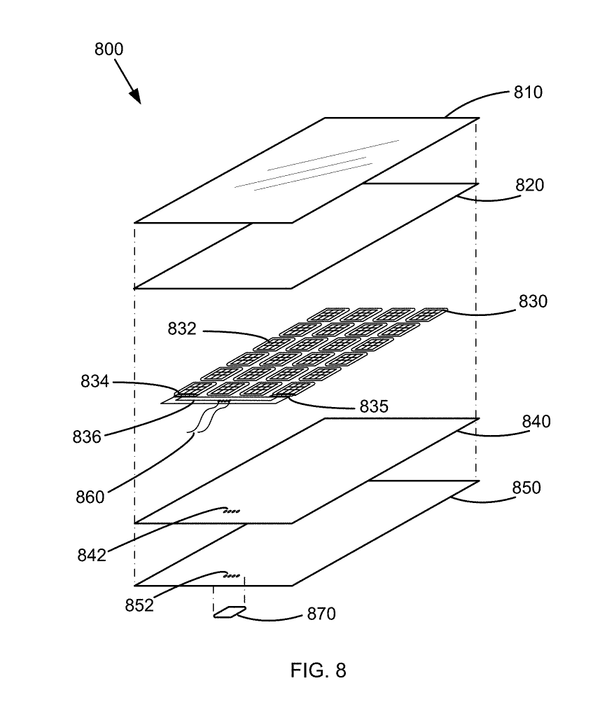

In some embodiments, flexible photovoltaic modules can be prepared as embodied in FIGS. 8-15, using solar cells with the free-standing metallic articles as disclosed herein. In some embodiments, the modules can be folded in a compact form and made easy to carry, such as in a backpack, to be unfolded and used later, such as in a more remote location. In other embodiments, the flexible modules may be folded for storage, such as in a rooftop or awning installation. Foldable modules also allow for easy installation and deployment due to a smaller size footprint during transportation and delivery. In other embodiments, the modules are flexible without necessarily being foldable, where the flexibility allows the modules to be used in environments where modules will undergo bending and flexing due to geometry and/or mechanical stresses. For example, flexible modules may be used in environments where high vibration or deflection of the module will occur, or where the modules must conform to a curved surface. The ability for photovoltaic modules to be flexible enables the modules to be used in a wider range of environments and applications, and increases reliability.

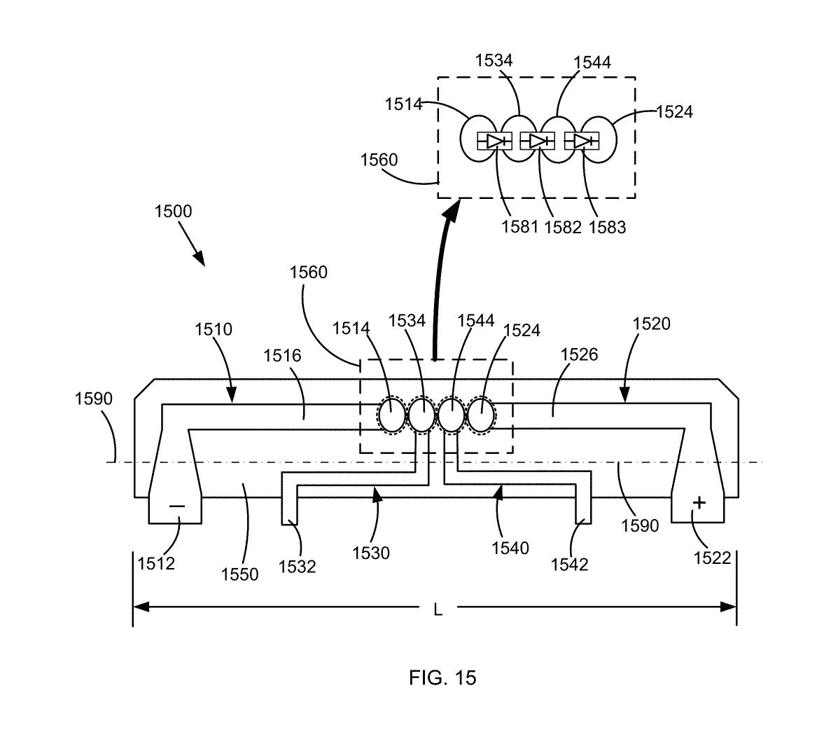

FIG. 8 is an exploded assembly view of the general structure of a flexible photovoltaic module assembly 800. A photovoltaic module layer 830 has photovoltaic cells 832 connected in series, with initial contact end 834 and final contact end 835 of the series of cells 832 being electrically coupled to a module circuit 836. The module circuit 836 may be a flexible module circuit, as shall be described in relation to FIG. 15. The photovoltaic cells 832, made with free-standing metallic articles, are assembled onto the module sheet 840, which may be an adhesive substrate material such as ethylene vinyl acetate (EVA). The photovoltaic cells 832 may also be coupled to a backsheet 850, which can be made of other polymer substrate materials including but not limited to polyethylene terephthalate (PET) or enhanced polyethylene (EPE). The photovoltaic cells 832 are also coupled to front sheets 810 and 820 which may be transparent superstrate materials such as ethylene tetrafluoroethylene (ETFE), transparent PET or encapsulant materials such as EVA or polyolefins (POE). The sheets 810, 820, 840 and 850 may be flexible to form a flexible photovoltaic module 800.

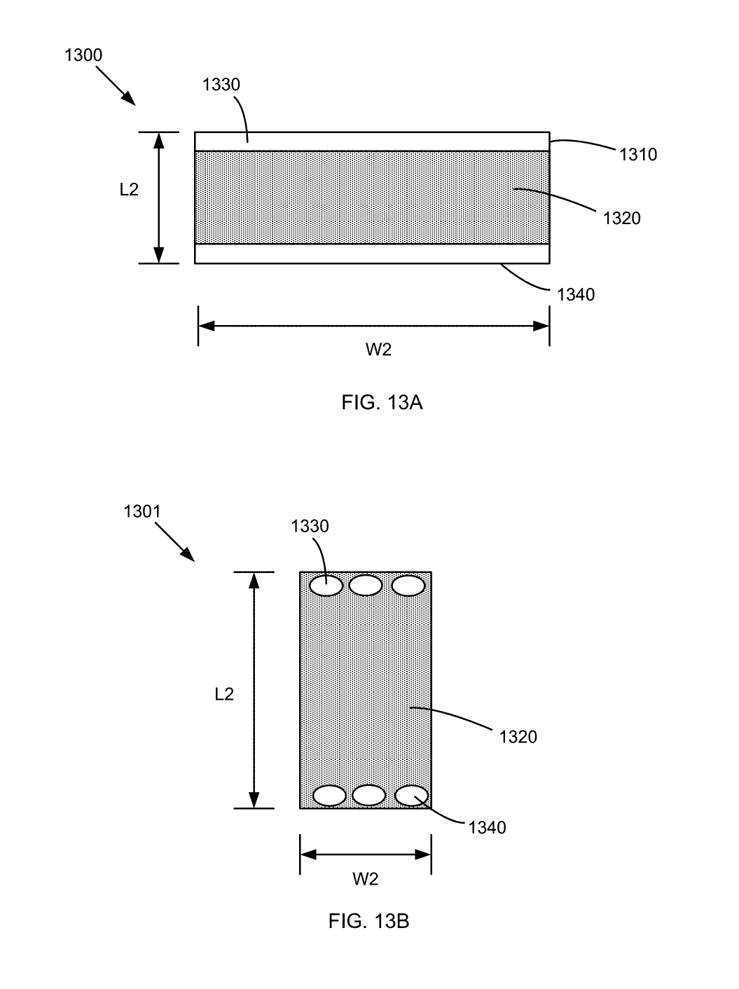

The cells 832 may be laid into place and have interconnection elements coupled together to adjacent cells, using manual or automated methods. For example, the cell-to-cell interconnections may be made using automated soldering and heating methods. The interconnections between cells can be made using interconnection elements that are integral to the free-standing metallic articles, such as cell interconnection element 620 of FIG. 6, or using separate components as shall be described in relation to FIGS. 13A-13B. The module circuit 836 may also be coupled to contact ends 834 and 835 of the series of cells 832 using automated soldering and heating methods, since the contact tabs of the module circuit 836 need only to be laid onto contact ends 834 and 835 rather than requiring threading and cutting of multiple bus bar ribbons as in conventional modules.

The cells 832 can be sandwiched between sheets 820 and 840, to encapsulate the cells 832. Sheet 820 may be, for example, EVA, or POE. Backing sheet 850, such as a polyvinyl fluoride (PVF) film (e.g., Tedlar®, or Tedlar-polyester-Tedlar), encloses the back side of the assembly 800. Transparent front sheet 810 such as glass or a flexible ETFE sheet covers the front of the assembly, to provide protection from environmental conditions. The entire layered stack may be put in a laminator, where heat and vacuum are applied to laminate the assembly. To complete the module, output connection wires 860 are routed from the module's flexible circuit 836, through holes 842 and 852 in EVA layer 840 and backing sheet 850, respectively, to junction box 870 on the back of the module assembly 800.

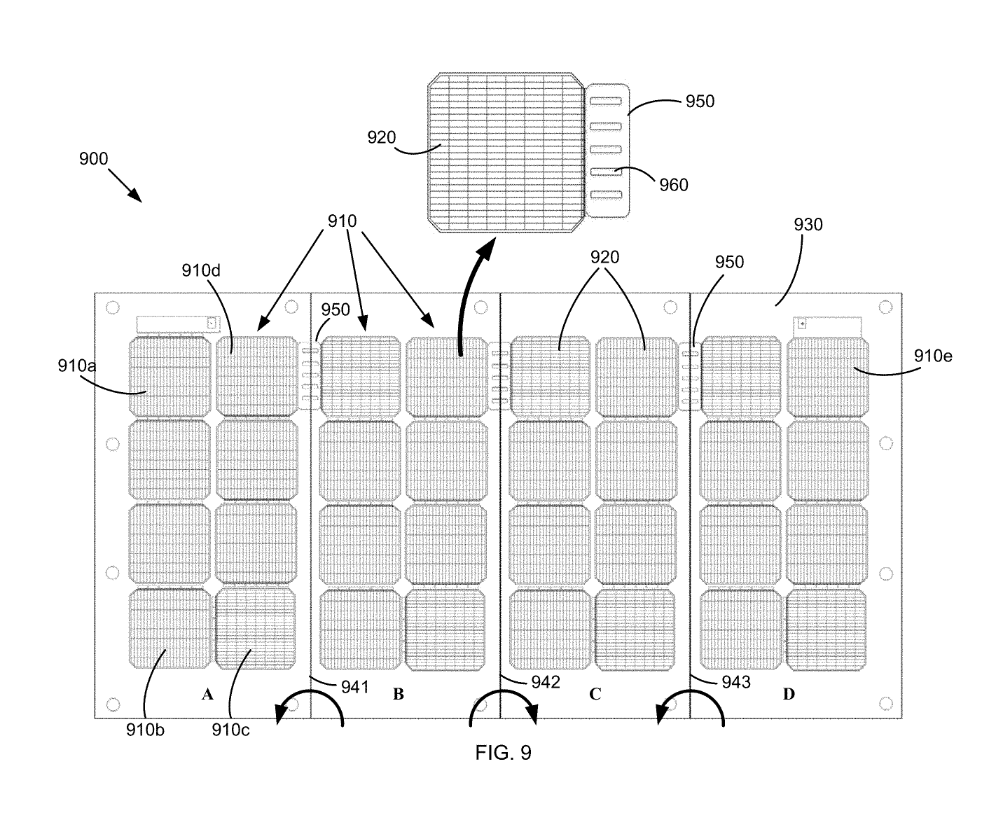

FIG. 9 shows a module 900 that is flexible in that it is foldable, where the folds are along parallel lines in this embodiment. The module 900 includes thirty-two separate cells 910 in this embodiment, each comprising a metallic article 920 attached to a semiconductor substrate. The cells 910 are positioned on a backing substrate 930, which may be made of known backing materials for photovoltaic modules, and may be rigid or flexible. Backing substrate 930 is segmented, such as by folding or scoring, to form fold lines 941, 942 and 943. The cells 910 are electrically connected in series, in a serpentine order from the first cell 910a to the fourth cell 910b, to the fifth cell 910c, to the eighth cell 910d, and so on to the last cell 910e. Electrical connections between cells 910 can be achieved using features of the metallic articles as described above, such as by using integral cell interconnection elements or separate connecting components.

For interconnections between cells that lie across fold lines 941, 942, and 943 in FIG. 9, foldable interconnections 950 are provided. For example, the connection from cell 910d to the next set of cells crosses fold line 941. Thus, the metallic article for 910d is designed with a foldable interconnection 950, while the interconnection between cells 910b and 910c does not cross a fold line, and therefore does not have a foldable interconnection between them. The foldable interconnections 950 can be a solid piece of material, such as a sheet or strip of copper, with a thickness sufficient to allow it to be readily folded without cracking or breaking. Thus, foldable interconnection 950 serves as a living hinge. In some embodiments, foldable interconnection 950 may include openings 960 that provide additional flexibility. The foldable interconnection 950 may be, for example, an elongated version of the interconnections between non-folding cells. In some embodiments, the foldable interconnections 950 can be integral components that are electroformed as part of the metallic articles. In other embodiments, the foldable interconnections 950 can be elements that are formed separately from the metallic articles, such as by electroforming or stamping, and subsequently joined to the metallic articles of the required cells. By arranging cells 910 and foldable interconnections 950 on substrate 930 as shown, with interconnections 950 straddling fold lines 941, 942 and 943, the resulting module 900 can be folded. In the embodiment of FIG. 9, fold lines 941 and 943 are foldable as a mountain fold, while fold line 942 is foldable as a valley fold, as indicated by the curved arrows. Consequently, the module 900 is folded such that panels A, B, C, and D stack on top of each other.

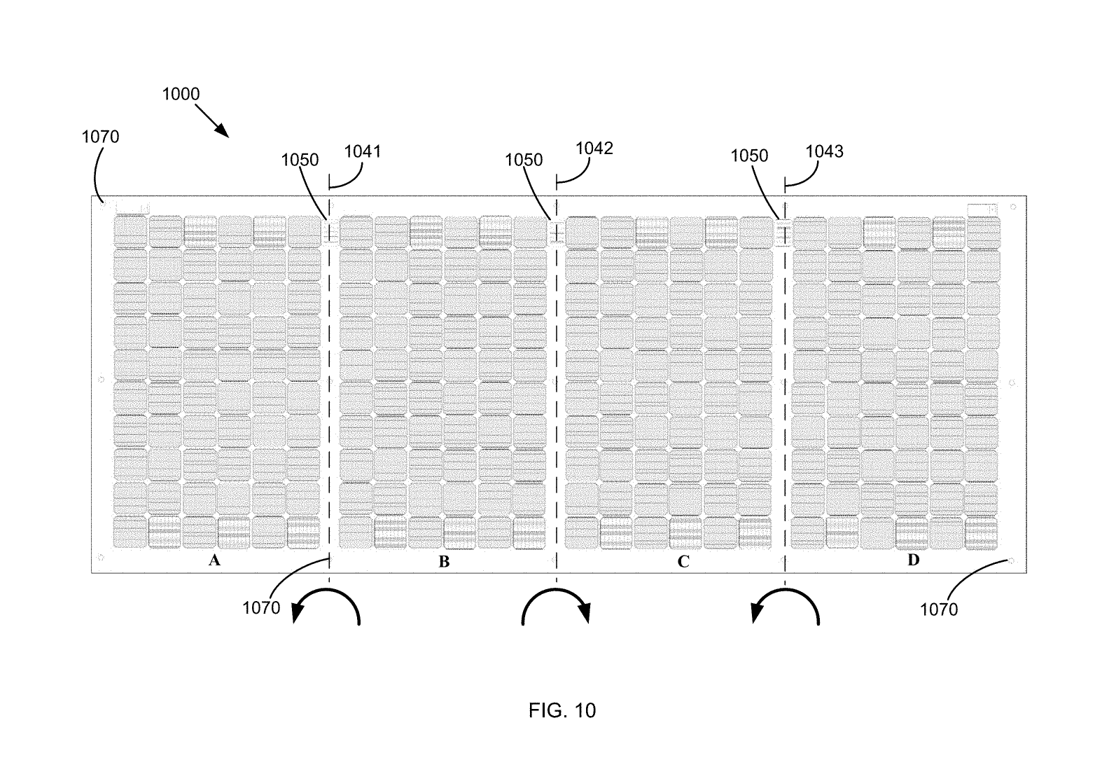

FIG. 10 shows another embodiment of a flexible module 1000 similar to FIG. 9, but with a greater number of cells. Flexible module 1000 has fold lines 1041, 1042 and 1043 between panels A, B, C and D, with foldable interconnections 1050 across the fold lines 1041, 1042 and 1043. Module 1000 may be folded accordion-style similarly to module 900, such as with fold lines 1041, 1042 and 1043 alternating between mountain folds and valley folds. Also shown in FIG. 10 are holes 1070 which enable a pull cord such as a cable or guide wire to contract the module into a folded configuration. Holes 1070 in this embodiment are positioned at the edges of the module 1000, and near the fold lines 1041, 1042 and 1043 to apply tension at the folding joints. Holes 1070 may include reinforcements such as eyelets or grommets, to increase durability. A cable mounting system as described with folding module 1000 may be used, for example, for opening and storage of an awning type of photovoltaic module.

Although the foldable interconnections in FIGS. 9 and 10 are shown as approximately rectangular, other shapes are possible. Additionally, although the foldable interconnections in FIGS. 9 and 10 are shown as centered along the edge of a cell and encompassing approximately most of the edge length, in other embodiments the foldable interconnections may extend along only a portion of an edge of a cell, or may be off-centered along the edge, such as at a corner. The specific configuration of the foldable interconnect may be designed to accommodate the fold geometry of a particular module.

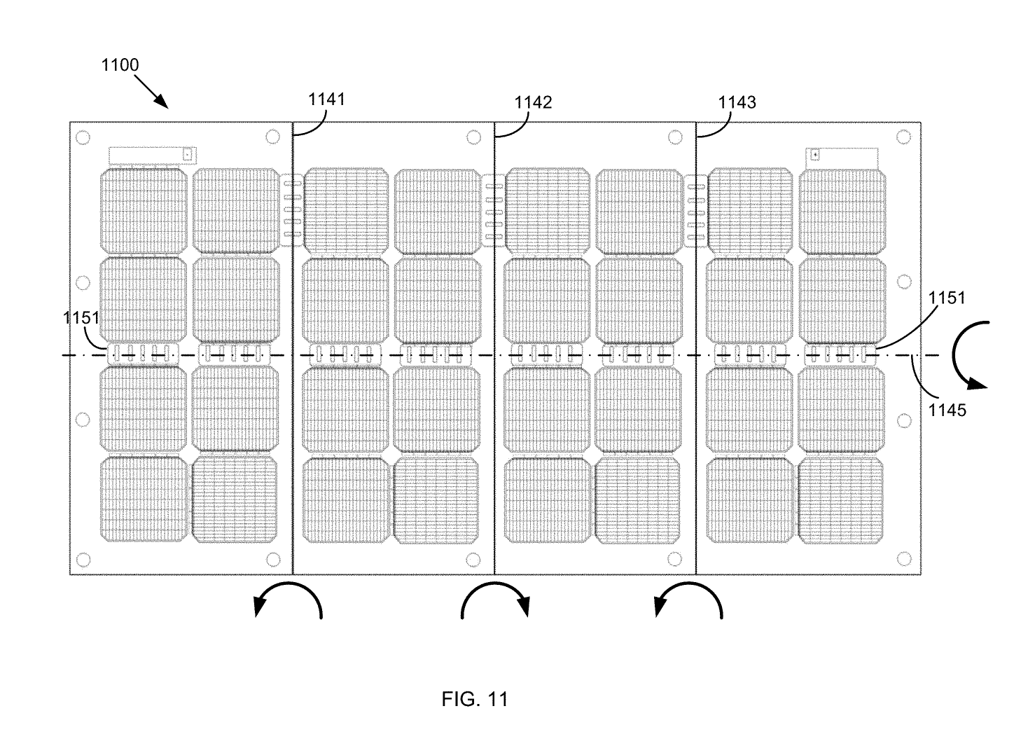

FIG. 11 shows a further embodiment of a flexible module 1100 that has bi-directional folding capability. In addition to vertical fold lines 1141, 1142 and 1143, module 1100 has a horizontal fold line 1145 that extends through approximately the mid-line of the module 1100 in this embodiment. Accordingly, foldable interconnections 1151 are utilized between adjacent cells that lie across the fold line 1145. The module 1100 may consequently be folded to a compact size in two directions, similar to a road map. For example, the module 1100 may be folded in half along fold line 1145, and then accordion folded along fold lines 1141, 1142 and 1143, as indicated by the curved arrows.

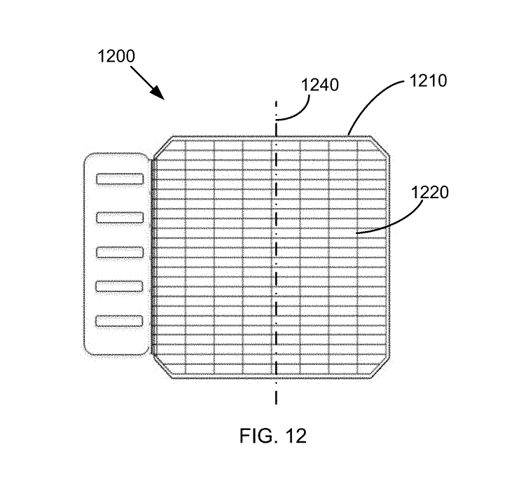

FIG. 12 illustrates an alternative method of forming flexible modules that takes advantage of the mechanical support provided by the metallic article attached to the cell. For example, the semiconductor substrate 1210 of solar cell 1200 can be scored or otherwise cut into separate pieces along dashed line 1240 while metallic article 1220 is attached. As long as the grid of the metallic article 1220 remains intact, the separate pieces of the semiconductor substrate 1210 will remain attached to the cell 1200, and as a result, the cell 1200 is capable of bending or flexing along the cut line 1240. Additional scoring and cut line formation would provide additional degrees of flexibility. For example, the semiconductor substrate can be scored into 2 to 36 sections in some embodiments. In this way, an individual cell with an attached metallic article as described herein can be made to be flexible, allowing it to fit along a curved or uneven surface as part of a module, particularly when combined with foldable interconnections such as is shown in FIGS. 9-11. Other additional benefits and properties will become apparent to one of ordinary skill in the art given the detailed description provided herein.

FIGS. 13A-13B are top-view depictions of embodiments of electrical conduits 1300 and 1301 for use in the interconnection of photovoltaic cells that have free-standing metallic articles electrically coupled to semiconductor substrates. The electrical conduits 1300 and 1301 are separate components from the free-standing metallic articles, and are used to electrically couple neighboring solar cells together while enabling the photovoltaic module to be mechanically flexible. The electrical conduits 1300 and 1301 are made of a flexible strip of an electrically conductive material 1310, such as a copper sheet.

In the embodiment of FIG. 13A, a conduit support sheet 1320 covers a first surface of the electrical conduit 1300 (e.g., the top surface in this view) except at opposite edges such that conduit contact tabs 1330 and 1340—which may also be referred to as pads in this disclosure—are formed by the exposed regions. Conduit support sheet 1320 is an electrically insulating material. The first and second conduit contact tabs 1330 and 1340 are embodied in FIG. 13A as strips along opposite ends (top and bottom edges) of the electrical conduit 1300, for proximity to the photovoltaic cells to which they are to be coupled. That is, the electrical conduit 1300 has a first conduit contact tab 1330 at a first end of the electrical conduit and a second conduit contact tab 1340 at a second end of the electrical conduit. The first conduit contact tab 1330 is a first region extending across the first end of the electrical conduit 1300, and the second conduit contact tab 1340 is a second region extending across the second end of the electrical conduit 1300.

In this embodiment of FIG. 13A, conduit contact tabs 1330 and 1340 are approximately flush with the edges of the electrical conduit 1300, for photovoltaic cells that may have an interconnection that extends beyond the body of the cell (e.g., interconnect 620 of FIG. 6). This type of contact tab may also be used, for example, where the photovoltaic cell to which it is connecting does not have an extending interconnect. For example, tabs 1330 and 1340 may be used to connect with a metallic article 660, which has flush edges, such as on the back side of solar cell 650 of FIG. 6. Having two contact pads, such as 1330 and 1340 in FIG. 13, for making electrical connections for photovoltaic cells enables mechanical and electrical assembly that is easily automatable.

FIG. 13B shows another embodiment of contact pads 1330 and 1340 in an electrical conduit 1301, where apertures are cut in the support sheet 1320 to enable connections for contact pads 1330 and 1340. In FIG. 13B, the support sheet 1320 extends to the ends of the electrical conduit 1301, with the contact tabs 1330 and 1340 remaining uncovered or exposed through apertures cut in and near the ends of the support sheet 1320 to allow for electrical connections to be made. Three ovular apertures are illustrated at each end of electrical conduit 1301 in this embodiment, although other numbers and shapes are possible for forming contact pads 1330 and 1340. The use of defined apertures rather than an entire edge to serve as contact pads enables coupling to a specific area of the cell interconnect (e.g., cell interconnect 620 of FIG. 6). Defined apertures also enable additional manufacturing techniques for the conduit 1301, including lithography or etching.

In various embodiments, both the front (i.e., top surface seen in FIGS. 13A-13B) and back surfaces (not visible in this plan view) of the electrical conduits 1300 and 1301 may be covered by support sheets 1320, between the regions of conduit contact tabs 1330 and 1340. The contact tabs 1330 and 1340 can be exposed on the front and/or back surfaces of the electrical conduit 1300, depending on if the connection is being made to the front or back surface of a photovoltaic cell. In some embodiments, the conduit contact pads 1330 and 1340 may be identical in size and shape at either end of the electrical conduit, which further enhances manufacturability and automation due to the symmetry of the conduit 1300.

The conduit support sheet 1320 of FIGS. 13A-13B covers a portion of the electrical conduits 1300 and 1301, and is an insulating dielectric layer such as polyethylene terephthalate (PET) or other polyester, or a polyimide. For example, support sheet 1320 may be PET or polyimide with a thickness of approximately 50 μm. The support sheet 1320 may be adhered, deposited, melted, or affixed onto the electrical conductive material 1310 using other methods. In the embodiment of FIGS. 13A-13B, the support sheet 1320 is attached to portions of the electrically conductive material 1310 in the non-contact region, enabling the contact tabs 1330 and 1340 to remain exposed for soldering to photovoltaic cells.

Electrically conductive material 1310 may be formed by, for example, electroforming, etching or stamping. Although the electrical conduits 1300 and 1301 are shown to be rectangular, other shapes are possible such as trapezoidal such that the width of one contact tab is different from the other; narrowed in width between the contact tabs 1330 to 1340, or L-shaped such that the contact tabs at the ends of the L are perpendicular to each other. The shape can be chosen according to the geometric constraints and/or flexibility requirements of the particular photovoltaic module.

The length L2 indicates the length of the electrical conduit 1300 from the end of one contact tab to another, while the width W2 is the width across one contact tab. The dimensions of the electrical conduits 1300 and 1301 are not shown to scale proportionally, for clarity of the components. For example, the width W2 of electrical conduit 1300 in FIG. 13A may be proportioned in variable amounts relative to the length L2. Similarly, the length L2 of electrical conduit 1301 may be proportioned differently relative to width W2 than what is illustrated in FIG. 13B.

The electrically conductive material 1310 of conduits 1300 and 1301 has sufficient thickness and surface area (width and length) to accommodate the electrical current capacity of an entire photovoltaic module. That is, the material volume of the electrical conduit may provide a high electrical current capacity such only one conduit is needed to interconnect photovoltaic cells to each other, compared to multiple stringing ribbons as in conventional solar modules. For example, the sheet thickness of the electrically conductive material 1310 may be on the order of 20-400 μm, such as 250-350 μm, with a total length ‘L2’ of 300-2000 mm, such as 400-500 mm, and a width ‘W2’ such as 25-50 mm for a module containing 6-72 cells. The current capacity for the electrical conduit (e.g., electrical conduit 1300 or 1301) may be, for example, 4-40 amperes, such as 8-12 amperes. The sheet thickness and surface area dimensions may be chosen to achieve the desired mechanical flexibility for the specific application. The flexible electrical conduits embodied by FIGS. 13A-13B provide flexibility for connecting cells in a module and enable unique folding module architectures through more robust mechanical and electrical performance when compared to conventional wires or ribbons.

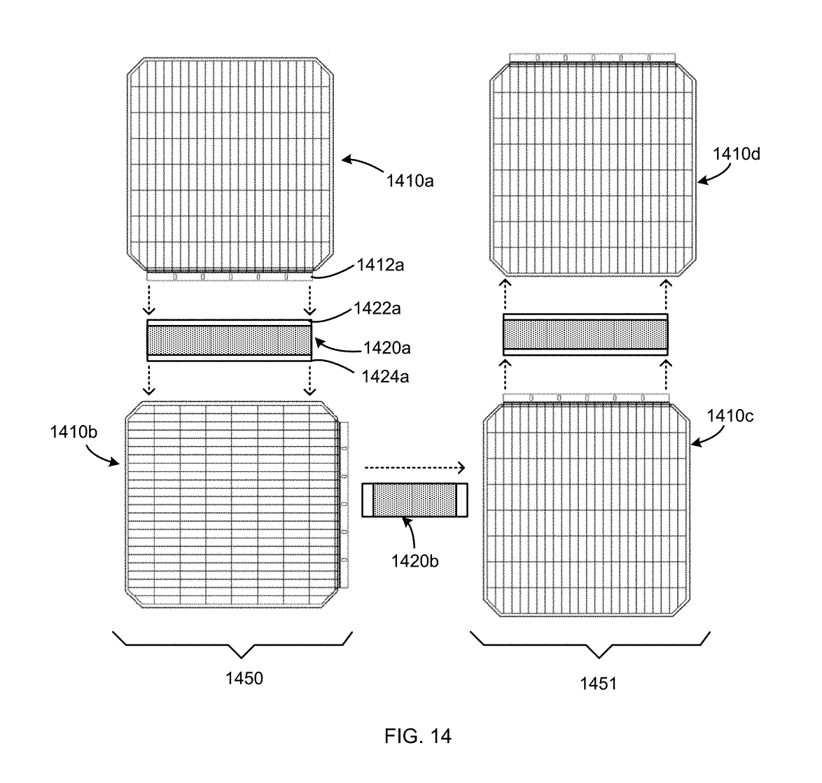

FIG. 14 shows a schematic of photovoltaic cells 1410 and interconnecting electrical conduits 1420 laid out for assembly onto a flexible photovoltaic module, in accordance with some embodiments. The photovoltaic cells 1410 (1410a, 1410b, 1410c, 1410d) have free-standing metallic articles as described previously herein, such as shown in FIG. 6. The photovoltaic cells 1410 are interconnected to each other using electrical conduits 1420 (1420a, 1420b) that are made of a flexible strip of electrically conductive material. Each electrical conduit 1420 electrically couples the cell interconnection element of a first photovoltaic cell in the plurality of photovoltaic cells to a neighboring second photovoltaic cell in the plurality of photovoltaic cells. The flexible electrical conduits enable a customizable range of motion and variable spacing of photovoltaic cells in a series connection, by tailoring the dimensions of the electrical conduits 1420.

The flexible electrical conduits 1420 may be used to connect cells within a row or between rows of a photovoltaic module, where the rows are shown in a vertical arrangement in this illustration. First row 1450 includes photovoltaic cells 1410a and 1410b, while second row 1451 includes cells 1410c and 1410d. Within first row 1450, photovoltaic cell 1410a and 1410b are electrically coupled together using electrical conduit 1420a. First conduit contact tab 1422a of electrical conduit 1420a is electrically coupled the cell interconnection element 1412a of photovoltaic cell 1410a. The second conduit contact tab 1424a of electrical conduit 1420a is coupled to a bottom surface of the neighboring photovoltaic cell 1410b. The bottom surface is opposite the light-incident surface, and has a back side metallization (not seen in this plan view) for photovoltaic cell 1410b, to which the second conduit contact tab 1424a is coupled. To couple first row 1450 to second row 1451, electrical conduit 1420b is used to interconnect photovoltaic cell 1410b of the first row 1450 to neighboring photovoltaic cell 1410c in the second row 1451. In this embodiment, electrical conduit 1420b is elongated in length compared to electrical conduit 1420b, such as to span a gap between rows 1450 and 1451. Thus, a variable spacing between cells can be achieved using the electrical conduits 1420. The electrical conduits 1420 of FIG. 14 may also be used in any of the foldable modules of FIGS. 9-11. The photovoltaic cells 1410a-1410d, along with other cells of the module, can be mounted on a flexible backing substrate. The flexible backing substrate may be an entirely flexible material, or may be a rigid material. Fold lines can be incorporated into either the rigid or flexible substrates. In some embodiments, the electrical conduits 1420a and/or 1420b may span a fold line of the photovoltaic module.

FIG. 15 shows a flexible module circuit 1500 described in U.S. patent application Ser. No. 14/636,864, that can be used to make external electrical connections for an entire photovoltaic module. The flexible module circuit 1500 can be serve as, for example, the module circuit 836 of FIG. 8. The flexible module circuit 1500 can be used in conjunction with the flexible electrical conduits of FIGS. 13A-13B to further enhance the mechanical flexibility of a solar module.

Flexible module circuit 1500 has a first flexible circuit electrical conduit 1510, a second flexible circuit electrical conduit 1520, a third flexible circuit electrical conduit 1530 and a fourth flexible circuit electrical conduit 1540, all mounted on a flexible support sheet 1550. Flexible support sheet 1550 encompasses the entire length of flexible module circuit 1500 in this embodiment, and most of its width. Flexible support sheet 1550 is an insulating dielectric layer, such as a polymer. The polymer may be, for example, a polyester such as polyethylene terephthalate (PET), or a polyimide. Other low-cost polymers known for use in solar modules may also be utilized. First conduit 1510 of flexible module circuit 1500 has a first contact tab 1512 that provides a connection to an initial end of a series of cells, and is shown as a negative terminal in this embodiment. Similarly, second conduit 1520 has a second contact tab 1522 that provides a connection to a final end of a series of cells, shown as a positive terminal in this embodiment. Third and fourth conduits 1530 and 1540 have third and fourth contact tabs 1532 and 1542, respectively, that allow for connection to the series of cells. At least a portion of the flexible circuit electrical conduits 1510, 1520, 1530 and 1540 are attached to the flexible support sheet 1550, where portions of the conduits that are extend beyond the support sheet may be used for electrical connections. The conduits may be attached to support sheet 1550 of the flexible module circuit 1500 using, for example, adhesives. The flexible module circuit 1500 may include one support sheet 1550 underneath the flexible circuit electrical conduits 1510, 1520, 1530 and 1540. In other embodiments support sheets 1550 may be both underneath and overlying the conduits, such that the conduits 1510, 1520, 1530 and 1540 are sandwiched between the dielectric material. In such embodiments, two separate pieces of support sheets 1550 may be used, or alternatively, one support sheet 1550 may be placed under the conduits and then folded over the conduits.

At the opposite ends of the tabs 1512, 1522, 1532 and 1542 of conduits 1510, 1520, 1530 and 1540 are junction box contact pads 1514, 1524, 1534 and 1544, respectively, which are grouped together in junction box contact region 1560 to enable junction box connections for the overall module. The junction box contact pads 1514, 1524, 1534 and 1544 enable connection to bypass diodes. The flexible module circuit 1500 is configured with four conduits 1510, 1520, 1530 and 1540 for a module having six columns of cells, where a bypass diode, such as diode 1581, may be connected between adjacent pads 1514 and 1534 for a first pair of cell strings. A second bypass diode 1582 may be connected between adjacent pads 1534 and 1544 for another set of cell strings, and a third bypass diode 1583 may be connected between adjacent pads 1544 and 1524 for a final set of cell strings. Diodes 1581, 1582 and 1583 may be located in the junction box area, away from the photovoltaic cells. This separation of the diodes from the cells improves safety since any electrical arcing that may occur in the diodes will be separated from the cells. Depending on the number of cell strings in a module, the flexible module circuit 1500 may have different numbers of electrical conduits. For example, a module with only two columns of cells may only require two conduits in the flexible module circuit 1500, such as conduits 1510 and 1520, and may not require a diode. A module with a greater number of cell strings may incorporate more than four electrical conduits in the flexible circuit 1500.

The junction box contact pads 1514 and 1524 allow for an output connection for the junction box, to deliver the current from the entire module. Thus, the flexible module circuit 1500 allows for a minimal number of solder points between the series of cells and the output for the junction box. In some embodiments, the flexible circuit 1500 is designed with a high current capacity such that only one junction box is needed for an entire module, and the first and second contact pads 1512 and 1522 are the only junction points between the series of cells and the output connection of the junction box. In other embodiments, the flexible circuit 1500 may be folded over at line 1590, which allows the electrical conduits of flexible circuit 1500 to provide a large amount of surface area, for high current-carrying capability, while occupying less space on the overall module.

In the embodiment of FIG. 15, the junction box contact pads 1514, 1524, 1534 and 1544 are located between the first contact tab 1512 and the second contact tab 1522. That is, first contact pad 1512, second contact pad 1522, first junction box contact pad 1514 and second junction box contact pad 1524 are laterally spaced apart on the support sheet 1550, with the first junction box contact pad 1514 and the second junction box contact pad 1524 being between the contact tabs 1512 and 1522. Thus, the contact tabs 1512 and 1522 are positioned with enough space between them to be easily laid onto the beginning and ending cells in a series, while the junction box pads 1514 and 1524 are positioned close together to facilitate junction box wiring. Junction box contact pads in this embodiment are configured as round or oval metal pads, which provide a large area for easy electrical connection. The pads 1514, 1524, 1534 and 1544 may be pre-cleaned, thus simplifying the manufacturing process, rather than needing to clean the solder connections after backing sheets and other module layers are assembled.

Connector 1516 of conduit 1510 extends along the length of flexible circuit 1500 between contact tab 1512 and junction box contact pad 1514, to serve as a conduit between tab 1512 and pad 1514. Similarly, connector 1526 of conduit 1520 extends along flexible circuit 1500 between contact tab 1522 and junction box contact pad 1524. The dashed circles surrounding each contact pad 1514, 1524, 1534 and 1544 represent contact openings in the support sheet 1550, to enable wiring access to the contact pads. Conduits 1510, 1520, 1530 and 1540 are strips of conductive metal, such as copper, and can be made by, for example electroforming, etching, or stamping. The conduits 1510 and 1520 may be designed with sufficient thickness and surface area to have a high electrical current capacity for an entire photovoltaic module. The current capacity for flexible circuit 1500 may be, for example, 4-40 amperes, such as 8-12 amperes. In some embodiments, the sheet thickness of conduits 1510 and 1520 may be, for example, 20-400 μm, such as 100-200 μm. The length ‘L’ of the flexible circuit 1500 can be customized to span the edge of the photovoltaic module to which it is being attached. For example, ‘L’ may be on the order of 1 meter for a module of 60 cells.

The free-standing metallic articles, the cell interconnection elements of the metallic articles, the electrical conduits for coupling photovoltaic cells together, and the flexible module circuits disclosed herein can be used in various combinations with each other to make flexible photovoltaic modules. For example, in some embodiments, both the extended-length cell interconnection elements (e.g., cell-to-cell interconnections 950) and the flexible electrical conduits (e.g., FIGS. 13A-13B and 14) may be used within one photovoltaic module. In other embodiments, shortened cell interconnection elements (e.g., interconnections 620) may be present in all the photovoltaic cells of a module, and flexible electrical conduits may be used in areas where additional flexibility and/or spacing between cells is needed. In some embodiments, a flexible circuit (e.g., FIG. 15) may be used for the module's electrical connections. In some embodiments, other embodiments of flexible module circuits, as disclosed in U.S. patent application Ser. No. 14/636,864, may be utilized.

In embodiments of photovoltaic modules with a flexible module circuit of U.S. patent application Ser. No. 14/636,864, the flexible module circuit includes a junction box contact region, a first flexible circuit electrical conduit, a second flexible circuit electrical conduit, and a flexible support sheet. The first flexible circuit electrical conduit includes a first contact tab and a first junction box contact pad, the first junction box contact pad being in the junction box contact region. The second flexible circuit electrical conduit includes a second contact tab and a second junction box contact pad, the second junction box contact pad being in the junction box contact region. The first and second flexible circuit electrical conduits are mounted on the flexible support sheet in the junction box contact region. In some embodiments, the plurality of photovoltaic cells of the photovoltaic module is electrically connected in series, where the first contact tab of the flexible module circuit is electrically coupled to an initial photovoltaic cell of the series of photovoltaic cells, the second contact tab of the flexible module circuit is electrically coupled to a final photovoltaic cell of the series of cells, and the junction box contact region of the flexible module circuit is electrically coupled to a junction box of the photovoltaic module.

Although the embodiments herein have primarily been described with respect to photovoltaic applications, the methods and devices may also be applied to other semiconductor applications such as redistribution layers (RDL's) or flex circuits. Furthermore, the flow chart steps may be performed in alternate sequences, and may include additional steps not shown.

Reference has been made in detail to embodiments of the disclosed invention, one or more examples of which have been illustrated in the accompanying figures. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these embodiments. For instance, features illustrated or described as part of one embodiment may be used with another embodiment to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A photovoltaic module comprising:
a) a flexible backing substrate;
b) a plurality of photovoltaic cells mounted on the flexible backing substrate, each photovoltaic cell comprising a metallic article, the metallic article comprising:
a plurality of electroformed elements configured as an electrical component for a light-incident surface of the photovoltaic cell, the plurality of electroformed elements comprising a cell interconnection element integral with a continuous grid having a plurality of first elements intersecting a plurality of second elements;
wherein the plurality of electroformed elements is interconnected and integral, with the continuous grid in contact with the light-incident surface;
wherein the cell interconnection element is configured to extend beyond the light-incident surface and couples the continuous grid to a neighboring photovoltaic cell; and
c) an electrical conduit comprising a flexible strip of electrically conductive material, wherein the electrical conduit electrically couples the cell interconnection element of a first photovoltaic cell in the plurality of photovoltaic cells to a neighboring second photovoltaic cell in the plurality of photovoltaic cells.

2. The photovoltaic module of claim 1, wherein the electrical conduit comprises:
a first conduit contact tab at a first end of the electrical conduit;
a second conduit contact tab at a second end of the electrical conduit; and
a conduit support sheet covering a first surface of the electrical conduit between the first conduit contact tab and at the second conduit contact tab.

3. The photovoltaic module of claim 2, wherein the first conduit contact tab is a first region extending across the first end of the electrical conduit, and the second conduit contact tab is a second region extending across the second end of the electrical conduit.

4. The photovoltaic module of claim 2, wherein:
the first conduit contact tab is coupled to the cell interconnection element on the light-incident surface of the first photovoltaic cell; and
the second conduit contact tab is coupled to a bottom surface of the neighboring second photovoltaic cell, the bottom surface being opposite the light-incident surface.

5. The photovoltaic module of claim 2, wherein the conduit support sheet is an electrically insulating material.

6. The photovoltaic module of claim 1, wherein the electrical conduit has a material volume to accommodate an electrical current capacity of the entire photovoltaic module.

7. The photovoltaic module of claim 1, wherein:
the first photovoltaic cell is in a first row of the plurality of photovoltaic cells; and
the neighboring second photovoltaic cell is in a second row of the plurality of photovoltaic cells, such that the electrical conduit electrically couples the first row with the second row.

8. The photovoltaic module of claim 7, wherein:
the backing substrate of the photovoltaic module is segmented by a fold line between the first row and the second row; and
the electrical conduit spans the fold line.

9. The photovoltaic module of claim 1, further comprising a flexible module circuit, the flexible module circuit comprising:
a junction box contact region;
a first flexible circuit electrical conduit comprising a first contact tab and a first junction box contact pad, the first junction box contact pad being in the junction box contact region;
a second flexible circuit electrical conduit comprising a second contact tab and a second junction box contact pad, the second junction box contact pad being in the junction box contact region; and
a flexible support sheet, wherein the first and second flexible circuit electrical conduits are mounted on the flexible support sheet in the junction box contact region.

10. The photovoltaic module of claim 9, wherein:
the plurality of photovoltaic cells is electrically connected in series;
the first contact tab of the flexible module circuit is electrically coupled to an initial photovoltaic cell of the series of photovoltaic cells;
the second contact tab of the flexible module circuit is electrically coupled to a final photovoltaic cell of the series of cells; and
the junction box contact region of the flexible module circuit is electrically coupled to a junction box of the photovoltaic module.

11. A method of forming a photovoltaic module, the method comprising:
a) providing a flexible backing substrate;
b) mounting a plurality of photovoltaic cells on the flexible backing substrate, each photovoltaic cell comprising a metallic article, the metallic article comprising:
a plurality of electroformed elements configured as an electrical component for a light-incident surface of the photovoltaic cell, the plurality of electroformed elements comprising a cell interconnection element integral with a continuous grid having a plurality of first elements intersecting a plurality of second elements;
wherein the plurality of electroformed elements is interconnected and integral, with the continuous grid in contact with the light-incident surface;
wherein the cell interconnection element is configured to extend beyond the light-incident surface and couples the continuous grid to a neighboring photovoltaic cell; and
c) electrically coupling the cell interconnection element of a first photovoltaic cell in the plurality of photovoltaic cells to a neighboring second photovoltaic cell in the plurality of photovoltaic cells using an electrical conduit, wherein the electrical conduit comprises a flexible strip of electrically conductive material.

12. The method of claim 11, wherein the electrical conduit comprises:
a first conduit contact tab at a first end of the electrical conduit;
a second conduit contact tab at a second end of the electrical conduit; and
a conduit support sheet covering a first surface of the electrical conduit between the first conduit contact tab and at the second conduit contact tab.

13. The method of claim 12, wherein the first conduit contact tab is a first region extending across the first end of the electrical conduit, and the second conduit contact tab is a second region extending across the second end of the electrical conduit.

14. The method of claim 12, wherein the electrically coupling of step (c) comprises:
coupling the first conduit contact tab to the cell interconnection element on the light-incident surface of the first photovoltaic cell; and
coupling the second conduit contact tab to a bottom surface of the neighboring second photovoltaic cell, the bottom surface being opposite the light-incident surface.

15. The method of claim 12, wherein the conduit support sheet is an electrically insulating material.

16. The method of claim 11, wherein the electrical conduit has a material volume to accommodate an electrical current capacity of the entire photovoltaic module.

17. The method of claim 11, wherein:
the first photovoltaic cell is in a first row of the plurality of photovoltaic cells; and
the neighboring second photovoltaic cell is in a second row of the plurality of photovoltaic cells, such that the electrical conduit electrically couples the first row with the second row.

18. The method of claim 17, wherein:
the backing substrate of the photovoltaic module is segmented by a fold line between the first row and the second row; and
the electrical conduit spans the fold line.

19. The method of claim 11, further comprising providing a flexible module circuit, the flexible module circuit comprising:
a junction box contact region;
a first flexible circuit electrical conduit comprising a first contact tab and a first junction box contact pad, the first junction box contact pad being in the junction box contact region;
a second flexible circuit electrical conduit comprising a second contact tab and a second junction box contact pad, the second junction box contact pad being in the junction box contact region; and
a flexible support sheet, wherein the first and second flexible circuit electrical conduits are mounted on the flexible support sheet in the junction box contact region.

20. The method of claim 19, further comprising:
electrically connecting the plurality of photovoltaic cells in series;
electrically coupling the first contact tab of the flexible module circuit to an initial photovoltaic cell of the series of photovoltaic cells;
electrically coupling the second contact tab of the flexible module circuit to a final photovoltaic cell of the series of cells; and
electrically coupling the junction box contact region of the flexible module circuit to a junction box of the photovoltaic module.
